(19) United States
(12) Patent Application Publication
(10) Pub. No.: US 2005/0167721 A1
(43) Pub. Date: Aug. 4, 2005

(54) Memory cell with a vertical transistor and fabrication method thereof

(75) Inventors: Shian-Jyh Lin, Chiayi Hsien (TW); Yu-Sheng Hsu, Taoyuan (TW)

Correspondence Address: QUINTERO LAW OFFICE, 1617 BROADWAY, 3RD FLOOR, SANTA MONICA, CA, 90404, US

(73) Assignee: NANYA TECHNOLOGY CORPORATION, TAOYUAN (TW)

(21) Appl. No.: 10/845,909

(22) Filed: May 14, 2004

(30) Foreign Application Priority Data
Jan. 30, 2004 (TW) TW93102111

(51) Int. Cl. H01L 21/8242

(52) U.S. Cl. 257/302

(57) ABSTRACT

A memory cell with a vertical transistor has a semiconductor silicon substrate with a deep trench, in which the deep trench has a first sidewall region and a second sidewall region. A first insulating layer is formed overlying the first sidewall region. A second insulating layer is formed overlying the second sidewall region, in which the thickness of the first insulating layer is larger than the thickness of the second insulating layer. A gate electrode layer is sandwiched between the first insulating layer and the second insulating layer. A buried strap out-diffusion region is formed in the substrate adjacent to the second sidewall region, in which the buried strap out-diffusion region is located near the lower portion of the second insulating layer.

### BACKGROUND OF THE INVENTION

1. Field of the Invention

The invention relates to a memory cell with a vertical transistor and a deep trench capacitor, and more particularly to a vertical transistor formed in a deep trench, in which a buried strap out-diffusion region or a channel region is formed on single sidewall of the deep trench.

2. Description of the Related Art

As integrated circuit techniques have developed, DRAM devices have become more powerful, smaller, and faster, particularly in devices with increased memory capacitance. A DRAM cell comprises a transistor coupled to a capacitor. There is much interest in reducing the size of individual DRAM cells to increase their density and thereby increase memory capacitance and allow faster operation, but a planar capacitor occupies a large area, which conflicts with the need to reduce memory cell size. A three-dimensional technique has been developed to form a vertical transistor and a deep trench capacitor in the DRAM cell in order to reduce the area occupied and increase integration. There are, however, limitations in controlling a buried strap (BS) out-diffusion region, which is used as a drain of the vertical transistor and an electrical connection between the vertical transistor and the deep trench capacitor. As the size of vertical transistors is reduced, the adjacent BS out-diffusion regions are easily overlapped causing the BS merge phenomenon, resulting in serious current leakage.

FIG. 1 is a cross-section of a conventional BS out-diffusion region between a vertical transistor and a deep trench capacitor. A P-type semiconductor silicon substrate 10 has a deep trench DT and a deep trench capacitor 12 formed at the lower portion of the deep trench DT. An N⁺-type diffusion region 14 is used as a bottom electrode plate of the deep trench capacitor 12, a silicon nitride liner 16 is used as a dielectric of the deep trench capacitor 12, and a first polysilicon layer 18 with N⁺-type ion dopants is used as an upper electrode plate of the deep trench capacitor 12.

After completing the deep trench capacitor 12, a collar oxide layer 20 is formed on the sidewall of the middle portion of the deep trench DT. Then, a second polysilicon layer 22 with N⁺-type ion dopants is formed to fill the opening surrounded by the collar oxide layer 20. Next, a third polysilicon layer 24 and a top insulating oxide 28 are successively formed to cover the second polysilicon layer 22. By thermal diffusion, the N⁺-type ion dopants can diffuse from the second polysilicon layer 22 into the silicon substrate 10 through the third polysilicon layer 24, thus forming a BS out-diffusion region 26. The third polysilicon layer 24 is also called a buried strap.

Next, a gate insulating layer 30 is formed on the sidewall of the upper portion of the deep trench DT. Then, a fourth polysilicon layer 32 is formed to fill the opening surrounded by the gate insulating layer 30, thus serving as a gate electrode. Next, a source diffusion region is formed in the substrate 10 adjacent to the top of the deep trench DT, thus a vertical channel region is formed between the source diffusion region and the BS out-diffusion region 26.

The BS out-diffusion region 26 is used as a drain diffusion region of the vertical transistor, and used as an electrical connection between the vertical transistor and the deep trench capacitor 12. Since the BS out-diffusion region 26 must be large enough to cross the insulating oxide 28 in order to ensure the electrical connection, means of raising the thermal diffusion temperature and increasing the ion-doped concentration of the second polysilicon layer 22 are required. However, this easily causes the BS merge phenomenon to occur resulting in current leakage and short circuits.

Various process designs for shrinking the BS out-diffusion region 26 have been developed, but have difficulties in simplifying procedure and controlling the thermal diffusion mechanism, thus do not meet the requirements for a semiconductor device of the sub-nanometer generation.

### SUMMARY OF THE INVENTION

Accordingly, an object of the present invention is to provide a deep trench type DRAM cell having a vertical transistor, in which two gate insulating layers of different thickness are formed the two sidewalls of the deep trench so as to achieve two threshold voltages. This contributes to one active BS outdiffusion region formed on one sidewall of the deep trench.

Another object of the present invention is to provide a deep trench type DRAM cell having a vertical transistor, in which a collar dielectric layer covers one sidewall region of the deep trench to contribute a single BS out-diffusion region formed in the substrate adjacent to the other sidewall region of the deep trench, resulting in a channel region along a single sidewall of the deep trench.

According to the object of the invention, a memory cell with a vertical transistor comprising a semiconductor silicon substrate with a deep trench, in which the deep trench comprises a first sidewall region and a second sidewall region. A first insulating layer is formed overlying the first sidewall region. A second insulating layer is formed overlying the second sidewall region, in which the thickness of the first insulating layer is larger than the thickness of the second insulating layer. A gate electrode layer is sandwiched between the first insulating layer and the second insulating layer. A buried strap out-diffusion region is formed in the substrate adjacent to the second sidewall region, in which the buried strap out-diffusion region is located near the lower portion of the second insulating layer.

According to the object of the invention, a memory cell with a vertical transistor comprising a semiconductor silicon substrate with a deep trench, in which the deep trench comprises a first sidewall region and a second sidewall region. A first collar dielectric layer is formed overlying the first sidewall region. A second collar dielectric layer is formed overlying the second sidewall region. A conductive layer is formed in the deep trench and sandwiched by the first collar dielectric layer and the second collar dielectric layer, in which the conductive layer adjacent to the first sidewall region is partially covered by the first collar dielectric layer, and the conductive layer adjacent to the second sidewall region is fully covered by the second collar dielectric layer. A top insulating layer is formed overlying the conductive layer. A gate electrode layer is sandwiched between the first insulating layer and the second insulating layer. A buried strap out-diffusion region is formed in the substrate adjacent to the first sidewall region, in which the buried strap out-diffusion region is located near the conductive layer. A first insulating layer is formed over the top insulating layer and overlying the first sidewall region of the deep trench. A second insulating layer is formed over the top insulating layer and overlying the second collar dielectric layer on the second sidewall region of the deep trench. A gate electrode layer is formed in the deep trench and sandwiched by the first insulating layer and the second insulating layer.

### DESCRIPTION OF THE DRAWINGS

The present invention will become more fully understood from the detailed description given hereinbelow and the accompanying drawings, given by way of illustration only and thus not intended to be limitative of the present invention.

FIG. 1 is a cross-section of a conventional BS out-diffusion region between a vertical transistor and a deep trench capacitor.

FIGS. 2A to 2G are cross-sections illustrating a fabrication method of a vertical transistor according to the first embodiment of the present invention.

FIG. 3 is a top view illustrating the layout of the shielding layer and the deep trench.

FIGS. 4A-4F are cross-sections of a fabrication method for a vertical transistor according to the second embodiment of the present invention.

FIG. 5 is a top view illustrating the layout of the shielding layer and the deep trench.

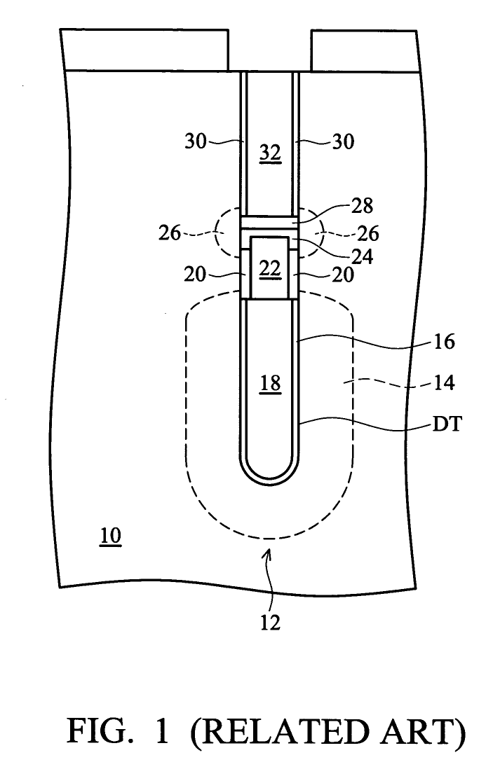

### DETAILED DESCRIPTION OF THE INVENTION

### First Embodiment

The first embodiment of the present invention provides a deep trench type DRAM cell having a vertical transistor, in which two gate insulating layers of different thickness are formed on both sidewalls of the deep trench so as to achieve two threshold voltages. Thus, a normal threshold voltage provided along one sidewall of the deep trench executes regular transistor performance, and a greater threshold voltage provided along the other sidewall of the deep trench cannot easily turn on the transistor. This contributes to only one active BS outdiffusion region being formed on one sidewall of the deep trench, thus preventing the BS merge phenomenon and ensuring the DRAM cell performance. The deep trench type DRAM cell with a vertical transistor is applicable to advanced semiconductor devices of sub-nanometer device.

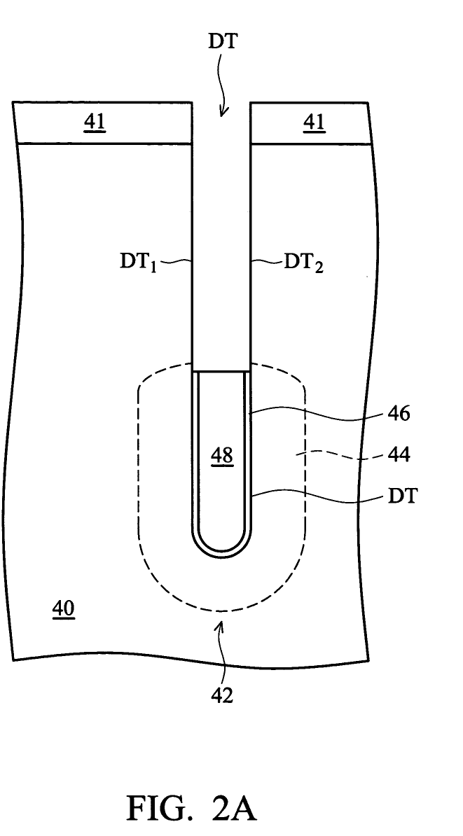

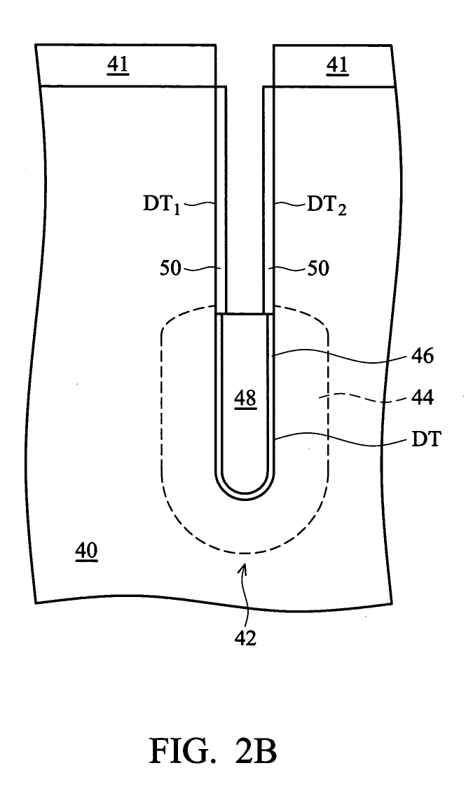

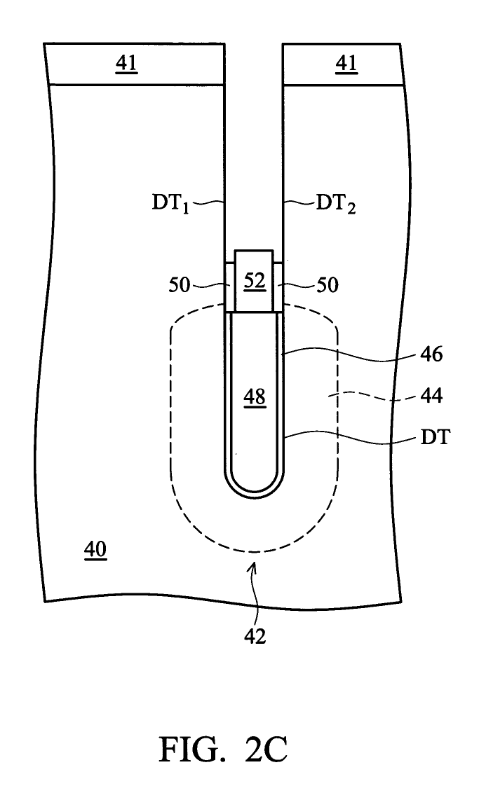

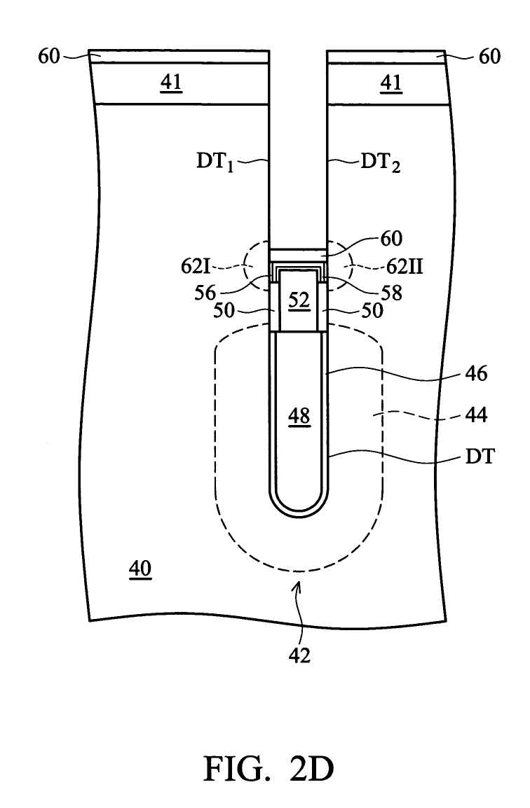

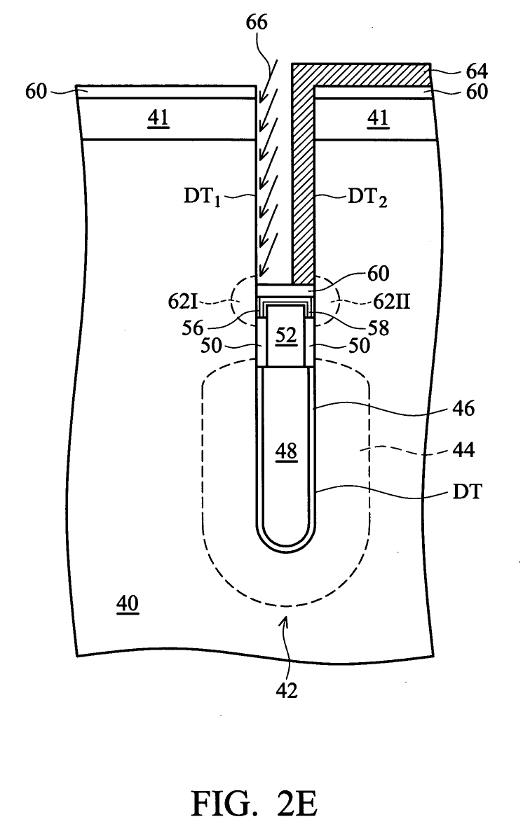

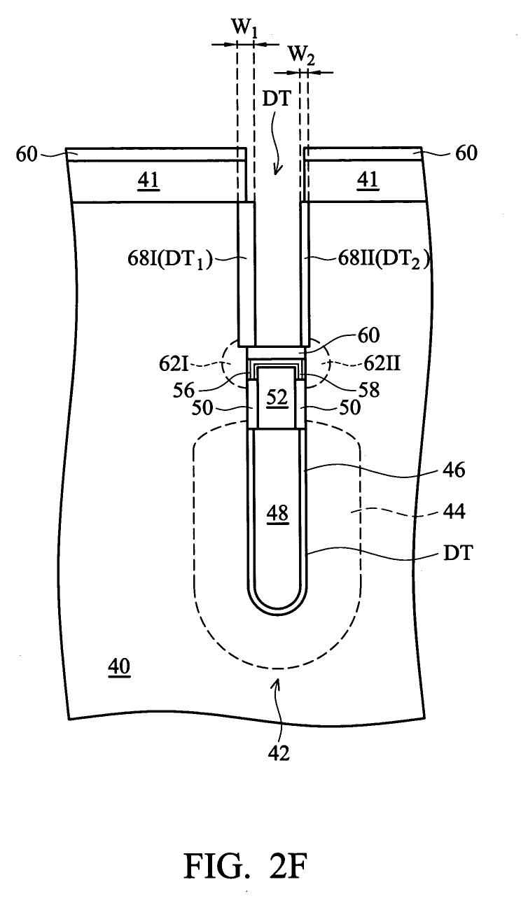

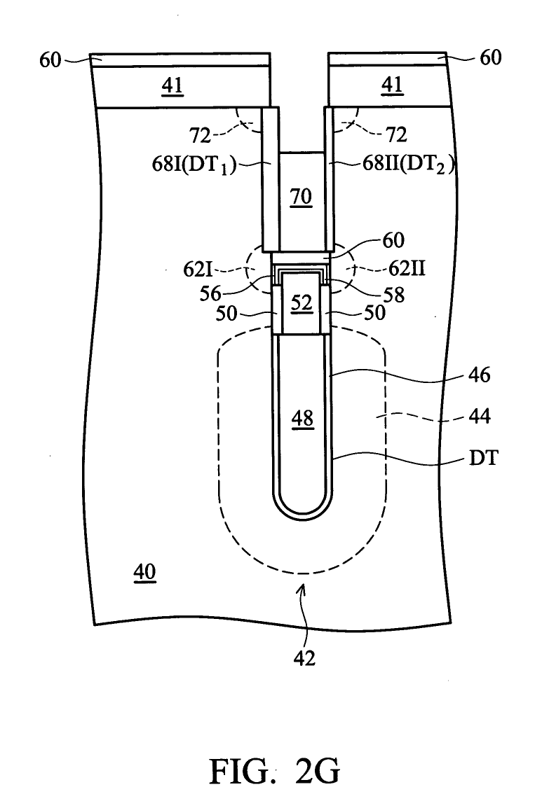

FIGS. 2A to 2G are cross-sections illustrating a fabrication method of a vertical transistor according to the first embodiment of the present invention.

In FIG. 2A, a semiconductor silicon substrate 40 has a deep trench capacitor 42 completed in a deep trench DT. A fabrication method for the deep trench capacitor 42 including a lower electrode plate 44, a capacitor dielectric 46 and an upper electrode plate 48 is described below. In the case of a P-type semiconductor silicon substrate 40, a pad layer 41 and an active ion etching (RIE) method are used to define a deep trench DT in the substrate 40. Preferably, the pad layer 41 is a stack of silicon nitride and silicon oxide. To clearly describe features of the present invention, the sidewall of the deep trench DT is defined as a first sidewall region DT₁ and a second sidewall region DT₂. Then, by depositing a heavily-doped oxide material, such as ASG, and performing a high-temperature short-term annealing, N⁺-type ions are diffused into the substrate 40 at the lower portion of the deep trench DT to form an N⁺-type diffusion region 44, serving as the lower electrode plate 44. Next, a dielectric layer 46 is formed on the bottom and sidewall of the deep trench DT. The dielectric layer 46 may be an oxide-nitride (ON) laminated structure or an oxide-nitride-oxide (ONO) laminated structure. Next, a first polysilicon layer 48 with N⁺-type ion dopants is deposited to fill the deep trench DT, and then etched back to reach a predetermined depth. Afterward, the dielectric layer 46 exposed outside the first polysilicon layer 48 is removed. Thereby, the first polysilicon layer 48 remaining in the lower portion of the deep trench DT serves as the upper electrode plate 48, and the dielectric layer 46 sandwiched between the first polysilicon layer 48 and the N⁺-type diffusion region 44 serves as the capacitor dielectric 46.

In FIG. 2B, a color dielectric layer 50 is formed on the first sidewall region DT₁ and the second sidewall region DT₂ to expose the top of the first polysilicon layer 48. Preferably, a collar dielectric process includes the following steps. First, a sacrificial oxide layer is grown on the exposed sidewall of the deep trench DT in order to ensure isolation between the N⁺-type diffusion region 44 and a BS out-diffusion region formed in subsequent processes. An oxide layer is then deposited on the sacrificial oxide layer by chemical vapor deposition (CVD) or another enforceable deposition method. Next, an anisotropic dry etching process is used to remove the oxide layer from the top of the first polysilicon layer 48. Preferably, the thickness of the collar dielectric layer 50 is 400˜100 Å.

In FIG. 2C, a second polysilicon layer 52 with N⁺-type ion dopants is deposited on the first polysilicon layer 48, and then a in-isotropic RIE method is used to etch back the second polysilicon layer 52 until a predetermined depth is reached. Next, wet etching is used to remove the collar dielectric layer 50 until the top of the second polysilicon layer 52 protrudes from the top of the collar dielectric layer 50.

In FIG. 2D, an interface layer 56, such as a silicon nitride liner, is formed on the second polysilicon layer 52, the first sidewall region DT₁ and the second sidewall region DT₂. Then, using deposition and wet etching, a third polysilicon layer 58 of a predetermined thickness is deposited in the deep trench DT. Next, using deposition and an etching back method, a top insulating layer 60 is deposited on the third polysilicon layer 58. Preferably, the top insulating layer 60 is a high-density plasma (HDP) oxide layer. Next, using a thermal diffusion process, the N⁺-type dopants of the second polysilicon layer 52 can diffuse into the substrate 40 through the third polysilicon layer 58, thus forming a first BS out-diffusion region 62I and a second BS out-diffusion region 62II on the first sidewall region DT₁ and the second sidewall region DT₂ respectively. The BS out-diffusion regions 62I and 62II provide the electrical connection between the deep trench capacitor 42 and a vertical transistor.

In FIG. 2E, a shielding layer 64 is formed to cover the second sidewall region DT₂ and expose the first sidewall region DT₁. Preferably, the shielding layer 64 is a bi-layer photoresist material, which is hardened by an exposure process. Next, using the shielding layer 64 as a hard mask and performing an ion implantation process 66, the surface bonding structure of the first sidewall region DT₁ is destroyed to contribute to a thicker oxide layer grown thereon in a subsequent process. Preferably, the ion implantation 66 uses fluorine as the ion source to perform tilt-angle implantation.

In FIG. 2F, after removing the shielding layer by a well known photoresist stripping method, a first insulating layer 68I and a second insulating layer 68II are grown on the first sidewall region DT₁ and the second sidewall region DT₂ respectively through a thermal oxidation process. Both the first insulating layer 68I and the second insulating layer 68II are silicon oxide layers. Since the ion implantation process 66 breaks the surface bonding structure of the first sidewall region DT₁, the thickness W₁ of the first insulating layer 68I is greater than the thickness W₂ of the second insulating layer 68II. Preferably, the thickness W₁ is 100˜200 Å, and the thickness W₂ is 20˜70 Å.

Finally, in FIG. 2G, using deposition, CMP and etching, a fourth polysilicon layer 70 is formed in the deep trench DT to serve as a gate electrode 70 of a vertical transistor. Then, a source diffusion region 72 is formed in the substrate 40 adjacent to the top sidewall of the deep trench DT, thus completing the vertical transistor.

For a vertical transistor adjacent to the first sidewall region DT₁, the gate insulating layer (the first insulating layer 68I of thickness W₁) is thicker to obtain a higher threshold voltage (Vt). For a vertical transistor adjacent to the second sidewall region DT₂, the gate insulating layer (the first insulating layer 68II of thickness W₂) is thinner to obtain a smaller threshold voltage (Vt). After applying voltage, the current passes through only the second insulating layer 68II with a smaller thickness W₂ to turn on the vertical transistor adjacent to the second sidewall region DT₂, without turning on the vertical transistor adjacent to the second sidewall region DT₁ simultaneously. Accordingly, only the second BS out-diffusion region 62II serves as an active drain diffusion region to provide a normal threshold voltage for executing regular transistor performance.

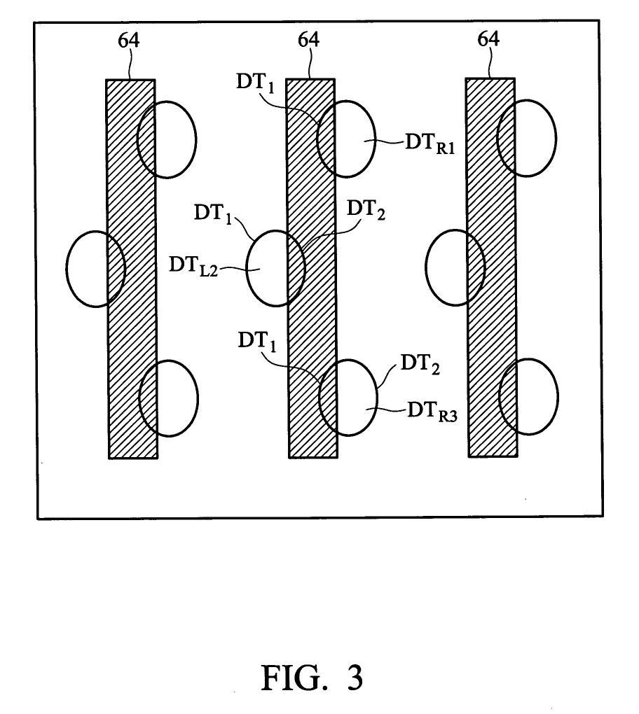

FIG. 3 is a top view illustrating the layout of the shielding layer and the deep trench. A well known layout design is implemented for deep trenches DT, deep trenches DT_{R1} are located along a first row, deep trenches DT_{L2} are located in along a second row, and deep trenches DT_{R3} are located along a third row. The deep trench DT_{R1} and the corresponding deep trench DT_{R3} are positioned in a first line at the right side of the corresponding deep trench DT_{L2} positioned in a second line. In the step described in FIG. 2E, each shielding layer 64 can simultaneously cover the first sidewall region DT₁ of the deep trench DT_{R1}, the second sidewall region DT₂ of the deep trench DT_{L2}, and the first sidewall region DT₁ of the deep trench DT_{R3}. Thus, a thinner gate insulating layer can be formed on the first sidewall regions DT₁ of the deep trench DT_{R1} and the deep trench DT_{R3}, and the second sidewall region DT₂ of the deep trench DT_{L2} so as to provide a normal threshold voltage for executing regular transistor performance.

### Second Embodiment

The second embodiment of the present invention provides a deep trench type DRAM cell having a vertical transistor, in which a collar dielectric layer remaining on one sidewall region of the deep trench to contribute a single BS out-diffusion region formed in the substrate adjacent to the other sidewall region of the deep trench, resulting in a channel region on a single sidewall region of the deep trench. This can prevent the BS merge phenomenon and ensure regular electrical performance of the DRAM cell. The deep trench type DRAM cell with a vertical transistor is applicable to advanced semiconductor devices of the sub-nanometer generations.

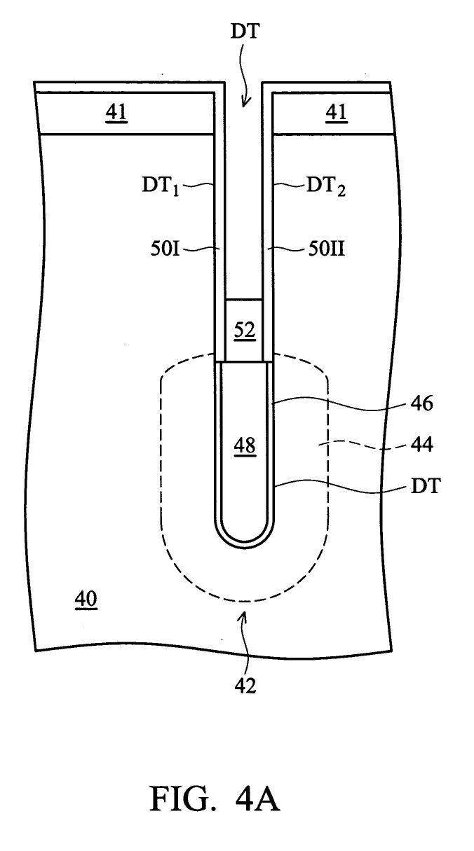

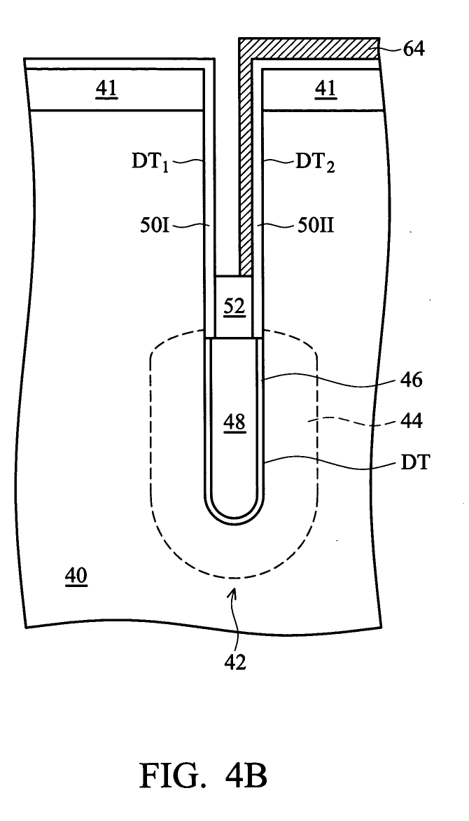

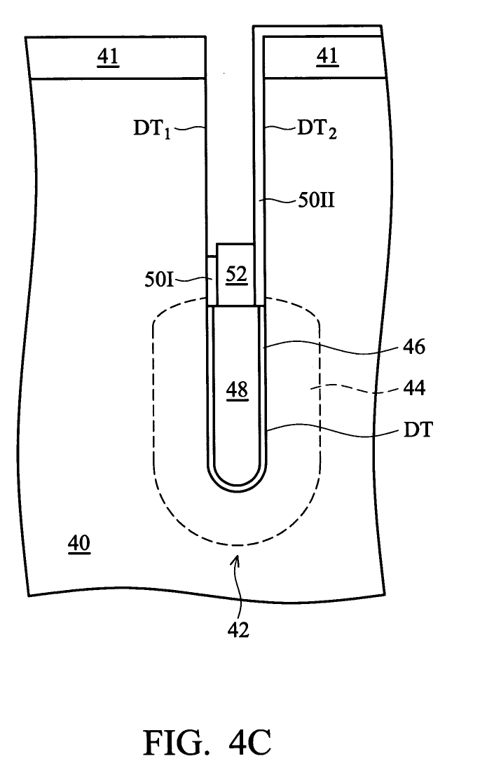

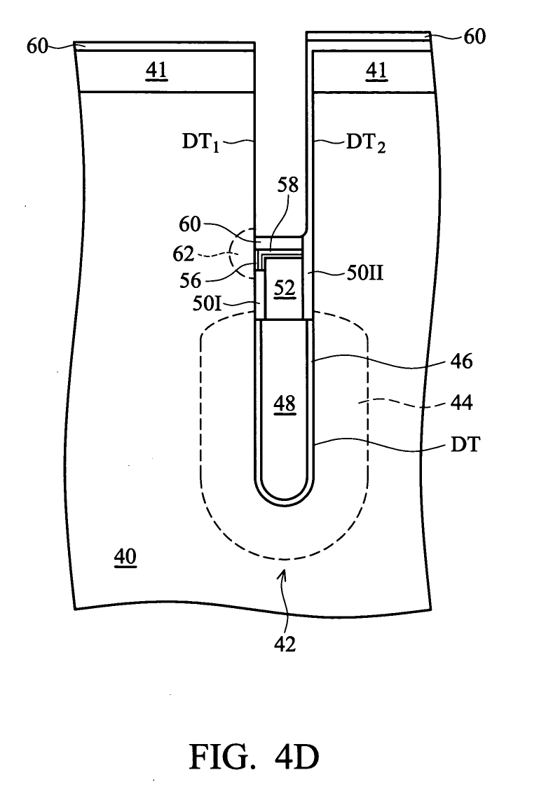

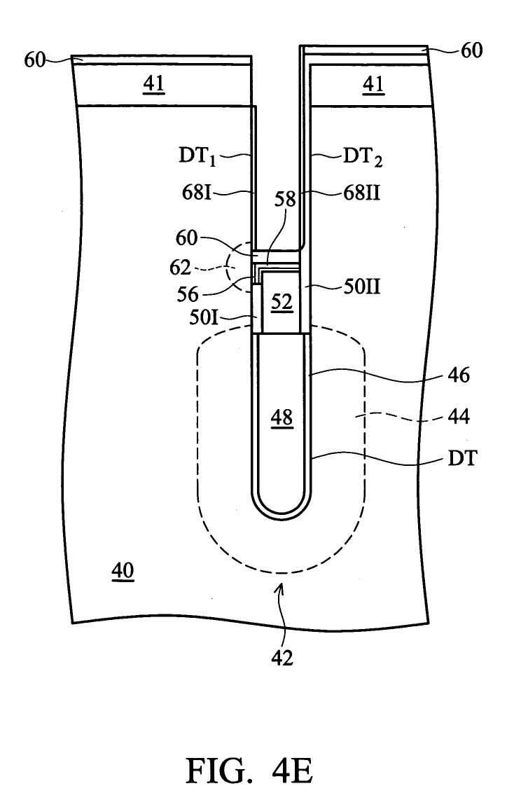

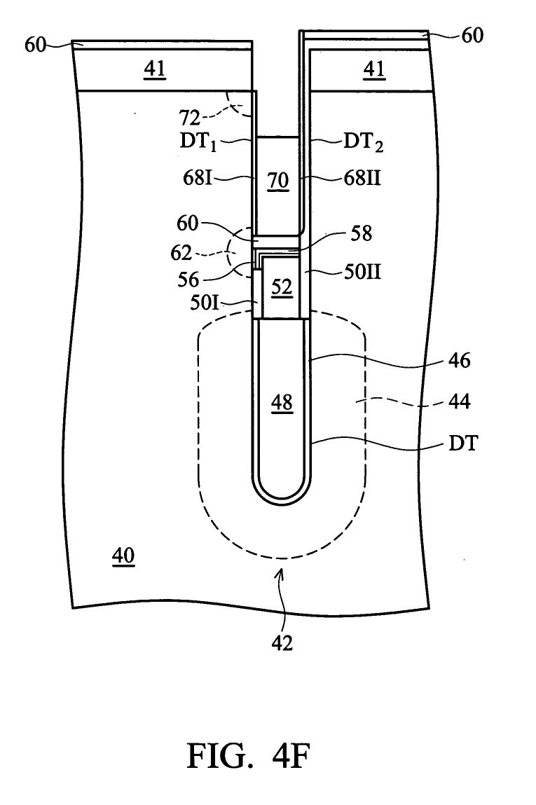

FIGS. 4A˜4F are cross-sections of a fabrication method for a vertical transistor according to the second embodiment of the present invention. Elements similar to those described in FIGS. 2A˜2G are omitted bellow.

In FIG. 4A, a deep trench capacitor 42 is completed in the deep trench DT of the substrate 40, including an N+-type diffusion region 44, a dielectric layer 46 and a first polysilicon layer 48. Then, a first collar dielectric layer 50I and a second collar dielectric layer 50II are formed on the first sidewall region DT₁ and the second sidewall region DT₂ respectively to expose the top of the first polysilicon layer 48. Next, a second polysilicon layer 52 with N⁺-type dopants is deposited in the deep trench DT, and then etched back to reach a predetermined depth.

In FIG. 4B, a shielding layer 64 is formed to cover the second collar dielectric layer 50II on the second sidewall region DT₂, and expose the first collar dielectric layer 50I on the first sidewall region DT₁. Preferably, the shielding layer 64 is a bi-layer photoresist material, which is hardened by an exposure process. Next, using the shielding layer 64 as a hard mask and performing a dry etching process, the first collar dielectric layer 50I is removed until the top of the second polysilicon layer 52 protrudes from the top of the first collar dielectric layer 50I. Next, the shielding layer 64 is removed as shown in FIG. 4C.

In FIG. 4D, an interface layer 56 of silicon nitride is formed on the first sidewall region DT₁ and the second polysilicon layer 52, and then a third polysilicon layer 58 and a top insulating layer 60 are successively formed thereon. Next, using a thermal diffusion process, the N⁺-type dopants of the second polysilicon layer 52 can diffuse into the substrate 40 through the third polysilicon layer 58, thus forming a BS out-diffusion region 62 on the first sidewall region DT₁. The BS out-diffusion region 62 provides the electrical connection between the deep trench capacitor 42 and a vertical transistor, and also serves as a drain diffusion region of the vertical transistor. Since the second collar dielectric layer 50II covers the second sidewall region DT₂ to isolate the second sidewall region DT₂ from the second polysilicon layer 52 and the third polysilicon layer 58, the thermal diffusion process can not form another BS out-diffusion region on the second sidewall region DT₂.

In FIG. 4E, using thermal oxidation, low-pressure chemical vapor deposition (LPCVD) or other enforceable method, a first insulating layer 68I is formed on the first sidewall region DT₁, and a second insulating layer 68II is formed on the second collar dielectric layer 50II on the second sidewall region DT₂. Thus, the first insulating layer 68I adjacent to the BS out-diffusion region 62 serves as a gate insulating layer of the vertical transistor. Preferably, the first insulating layer 68I and the second insulating layer 68II are silicon oxide layers by in-situ steam generation (ISSG) technique.

Finally, in FIG. 4F, using deposition, CMP and etching, a fourth polysilicon layer 70 is formed in the deep trench DT to serve as a gate electrode 70 of the vertical transistor. Then, a source diffusion region 72 is formed in the substrate 40 adjacent to the top sidewall of the deep trench DT, thus completing the vertical transistor.

Since the second collar dielectric layer 50II covers the second sidewall region DT₂ to isolate the second sidewall region DT₂ from the second polysilicon layer 52 and the third polysilicon layer 58, the BS out-diffusion region 62 is only formed on the first sidewall region DT₁, thus providing a channel region along a single sidewall of the deep trench DT.

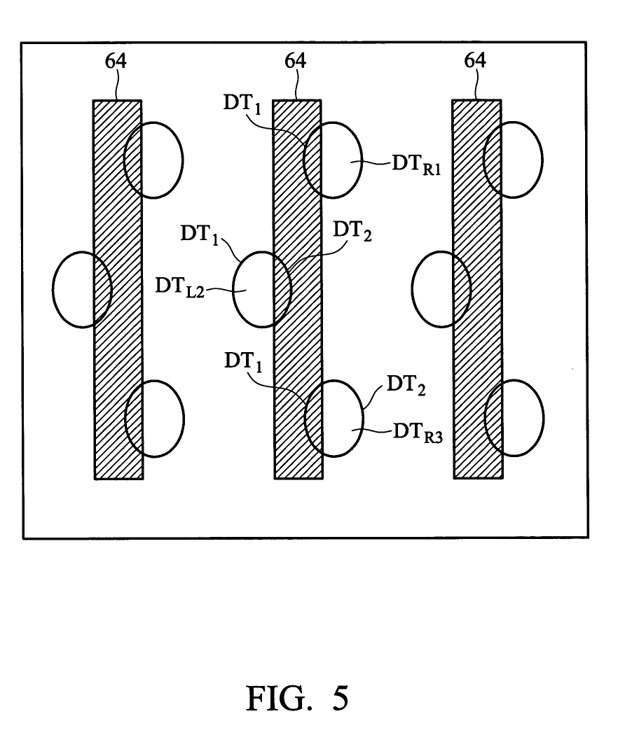

FIG. 5 is a top view illustrating the layout of the shielding layer and the deep trench. Elements similar to those in FIG. 3 are omitted below.

In the step described in FIG. 4B, each shielding layer 64 can simultaneously cover the first sidewall region DT₁ of the deep trench DT_{R1}, the second sidewall region DT₂ of the deep trench DT_{L2}, and the first sidewall region DT₁ of the deep trench DT_{R3}. Thus, the BS out-diffusion region 62 can be formed on the second sidewall regions DT₂ of the deep trench DT_{R1} and the deep trench DT_{R3}, and the first sidewall region DT₁ of the deep trench DT_{L2} so as to provide a channel region along a single sidewall of the deep trench.

While the invention has been described by way of example and in terms of the preferred embodiments, it is to be understood that the invention is not limited to the disclosed embodiments. To the contrary, it is intended to cover various modifications and similar arrangements (as would be apparent to those skilled in the art). Therefore, the scope of the appended claims should be accorded the broadest interpretation so as to encompass all such modifications and similar arrangements.

1. A memory cell with a vertical transistor, comprising:
a semiconductor silicon substrate comprising a deep trench, in which the deep trench comprises a first sidewall region and a second sidewall region;
a first insulating layer formed overlying the first sidewall region;
a second insulating layer formed overlying the second sidewall region, in which the thickness of the first insulating layer is larger than the thickness of the second insulating layer;
a gate electrode layer sandwiched between the first insulating layer and the second insulating layer; and
a buried strap out-diffusion region formed in the substrate adjacent to the second sidewall region, in which the buried strap out-diffusion region is located near the lower portion of the second insulating layer.

2. The memory cell with a vertical transistor as claimed in claim 1, wherein the second insulating layer contributes to a normal threshold voltage along the second sidewall region to turn on the vertical transistor, and the first insulating layer contributes to a higher threshold voltage along the first sidewall region without turning on the vertical transistor.

3. The memory cell with a vertical transistor as claimed in claim 1, further comprising a deep trench capacitor which comprises:
a first conductive layer filling the lower portion of the deep trench;
an ion-doped diffusion region formed in the substrate and surrounding the lower portion of the deep trench; and
a dielectric layer formed on the sidewall of the lower portion of the deep trench, and sandwiched between the first conductive layer and the ion doped diffusion region.

4. The memory cell with a vertical transistor as claimed in claim 3, further comprising:
a collar dielectric layer formed over the deep trench capacitor and overlying the first sidewall region and the second sidewall region of the deep trench;
a second conductive layer formed overlying the first conductive layer and surrounded by the collar dielectric layer, in which the top of the second conductive layer protrudes from the top of the collar dielectric layer;
a third conductive layer formed overlying the second conductive layer and the collar dielectric layer; and
a top insulating layer formed overlying the third conductive layer;
wherein, the first insulating layer is formed over the top insulating layer and overlying the first sidewall region of the deep trench;
wherein, the second insulating layer is formed over the top insulating layer and overlying the second sidewall region of the deep trench;

5. The memory cell with a vertical transistor as claimed in claim 4, wherein the collar dielectric layer is a silicon oxide layer.

6. The memory cell with a vertical transistor as claimed in claim 4, wherein the second conductive layer is an ion-doped polysilicon layer, and the third conductive layer is a polysilicon layer.

7. The memory cell with a vertical transistor as claimed in claim 4, wherein the top insulating layer is a silicon oxide layer.

8. The memory cell with a vertical transistor as claimed in claim 1, wherein the first insulating layer and the second insulating layer are silicon oxide layers.

9. The memory cell with a vertical transistor as claimed in claim 1, wherein the gate electrode layer is a polysilicon layer.

10. A fabrication method for a memory cell with a vertical transistor, comprising the steps of:
providing a semiconductor silicon substrate comprising a deep trench, in which the deep trench comprises a first sidewall region and a second sidewall region;
forming a first buried strap out-diffusion region and a second buried strap out-diffusion region in the substrate, in which the first buried strap out-diffusion region is adjacent to the first sidewall region of the deep trench, and the second buried strap out-diffusion region is adjacent to the second sidewall region of the deep trench;
forming a shielding layer to cover the second sidewall region of the deep trench;
using the shielding layer as a hard mask and performing an ion implantation process on the first sidewall region of the deep trench;
removing the shielding layer;
forming a first insulating layer on the first sidewall region of the deep trench, and forming a second insulating layer on the second sidewall region of the deep trench, in which the thickness of the first insulating layer is larger than the thickness of the second insulating layer; and
forming a gate electrode layer in the deep trench, in which the gate electrode layer is sandwiched between the first insulating layer and the second insulating layer;
wherein, the second buried strap out-diffusion region is located adjacent to the lower portion of the second insulating layer; and
wherein, the second insulating layer contributes to a normal threshold voltage along the second sidewall region for turning on the vertical transistor.

11. The fabrication method for a memory cell with a vertical transistor as claimed in claim 10, before the formation of the buried strap out-diffusion regions, further comprising the steps of:
forming a collar dielectric layer overlying the first sidewall region and the second sidewall region of the deep trench;
forming a second conductive layer in the deep trench and surrounded by the collar dielectric layer, in which the top of the second conductive layer protrudes from the top of the collar dielectric layer;
forming a third conductive layer overlying the second conductive layer and the collar dielectric layer; and
forming a top insulating layer overlying the third conductive layer;
wherein, the first buried strap out-diffusion region formed in the substrate adjacent to the first sidewall region of the deep trench is near the second conductive layer and the third conductive layer; and
wherein, the second buried strap out-diffusion region formed in the substrate adjacent to the second sidewall region of the deep trench is near the second conductive layer and the third conductive layer;

12. The fabrication method for a memory cell with a vertical transistor as claimed in claim 11, before the formation of the collar dielectric layer, further comprising the steps of:
forming an ion-doped diffusion region in the substrate and surrounding the lower portion of the deep trench;
forming a dielectric layer on the sidewall of the lower portion of the deep trench; and
forming a first conductive layer to fill the lower portion of the deep trench;
wherein, the ion-doped diffusion region surrounds the first conductive layer; and
wherein, the dielectric layer is sandwiched between the first conductive layer and the ion doped diffusion region.

13. The fabrication method for a memory cell with a vertical transistor as claimed in claim 10, wherein the shielding layer is a photoresist material which is hardened by an exposure process.

14. The fabrication method for a memory cell with a vertical transistor as claimed in claim 10, wherein the ion implantation uses fluorine as an ion source to perform tilt-angle implantation.

15. A memory cell with a vertical transistor, comprising:
a semiconductor silicon substrate comprising a deep trench, in which the deep trench comprises a first sidewall region and a second sidewall region;
a first collar dielectric layer formed overlying the first sidewall region;
a second collar dielectric layer formed overlying the second sidewall region;
a conductive layer formed in the deep trench and sandwiched by the first collar dielectric layer and the second collar dielectric layer, in which the conductive layer adjacent to the first sidewall region is partially covered by the first collar dielectric layer, and the conductive layer adjacent to the second sidewall region is fully covered by the second collar dielectric layer;
a top insulating layer formed overlying the conductive layer; and
a gate electrode layer sandwiched between the first insulating layer and the second insulating layer;
a buried strap out-diffusion region formed in the substrate adjacent to the first sidewall region, in which the buried strap out-diffusion region is located near the conductive layer;
a first insulating layer formed over the top insulating layer and overlying the first sidewall region of the deep trench;
a second insulating layer formed over the top insulating layer and overlying the second collar dielectric layer on the second sidewall region of the deep trench; and
a gate electrode layer formed in the deep trench and sandwiched by the first insulating layer and the second insulating layer.

16. The memory cell with a vertical transistor as claimed in claim 15, further comprising a deep trench capacitor which comprises:
a first polysilicon layer filling the lower portion of the deep trench;
an ion-doped diffusion region formed in the substrate and surrounding the lower portion of the deep trench; and
a dielectric layer formed on the sidewall of the lower portion of the deep trench, and sandwiched between the first polysilicon layer and the ion doped diffusion region.

17. The memory cell with a vertical transistor as claimed in claim 15, wherein each of the first collar dielectric layer and the second collar dielectric layer is a silicon oxide layer.

18. The memory cell with a vertical transistor as claimed in claim 15, wherein the conductive layer comprises:
a second polysilicon layer with ion dopants, in which the top of the second polysilicon layer protrudes from the top of the first collar dielectric layer, and the second polysilicon layer adjacent to the second sidewall region is fully covered by the second collar dielectric layer; and
a third polysilicon layer formed overlying the second polysilicon layer and covering the first collar dielectric layer.

19. The memory cell with a vertical transistor as claimed in claim 15, wherein the top insulating layer is a silicon oxide layer.

20. The memory cell with a vertical transistor as claimed in claim 15, wherein the first insulating layer and the second insulating layer is a silicon oxide layer.

21. The memory cell with a vertical transistor as claimed in claim 15, wherein the gate electrode layer is a polysilicon layer.

22. A fabrication method for a memory cell with a vertical transistor, comprising the steps of:
providing a semiconductor silicon substrate comprising a deep trench, in which the deep trench comprises a first sidewall region and a second sidewall region;
forming a first collar dielectric layer on the first sidewall region of the deep trench;
forming a second collar dielectric layer on the second sidewall region of the deep trench;
forming a first conductive layer in the deep trench, in which the first conductive layer is sandwiched by the first collar dielectric layer and the second dielectric layer;
forming a shielding layer to cover the second collar dielectric layer on the second sidewall region;
using the shielding layer as a hard mask and removing the first collar dielectric layer until the top of the first conductive layer protrudes from the top of the first collar dielectric layer;
removing the shielding layer;
forming a second conductive layer overlying the first conductive layer and the first collar dielectric layer, in which the second conductive layer adjacent to the second sidewall region is fully covered by the second collar dielectric layer;
forming a top insulating layer overlying the second conductive layer;
forming a buried strap out-diffusion region in the substrate adjacent to the first sidewall region of the deep trench, in which the buried strap out-diffusion region is located near the second conductive layer;
forming a first insulating layer overlying the first sidewall region of the deep trench;
forming a second insulating layer overlying the second collar dielectric layer on the second sidewall region; and
forming a gate electrode layer in the deep trench and sandwiched by the first insulating layer and the second insulating layer.

23. The fabrication method for a memory cell with a vertical transistor as claimed in claim 22, before the formation of the first collar dielectric layer and the second collar dielectric layer, further comprising the steps of:
forming an ion-doped diffusion region in the substrate and surrounding the lower portion of the deep trench;
forming a dielectric layer on the sidewall of the lower portion of the deep trench; and
forming a polysilicon layer to fill the lower portion of the deep trench;
wherein, the ion-doped diffusion region surrounds the first conductive layer; and
wherein, the dielectric layer is sandwiched between the polysilicon layer and the ion doped diffusion region.

24. The fabrication method for a memory cell with a vertical transistor as claimed in claim 22, wherein the shielding layer is a photoresist material which is hardened by an exposure process.

25. The fabrication method for a memory cell with a vertical transistor as claimed in claim 22, wherein the first collar dielectric layer and the second collar dielectric layer are silicon oxide layers.

26. The fabrication method for a memory cell with a vertical transistor as claimed in claim 22, wherein the first conductive layer is an ion-doped polysilicon layer, and the second conductive layer is a polysilicon layer.

27. The fabrication method for a memory cell with a vertical transistor as claimed in claim 22, wherein the top insulating layer is a silicon oxide layer.

28. The fabrication method for a memory cell with a vertical transistor as claimed in claim 22, wherein the first insulating layer and the second insulating layer are silicon oxide layers.
